(19) United States
(12) Patent Application Publication
(10) Pub. No.: US 2026/0150261 A1
(43) Pub. Date: May 28, 2026

(54) METHOD OF MANUFACTURING MEMORY DEVICE

(71) Applicant: Winbond Electronics Corp., Taichung Cit (TW)

(72) Inventor: Chang-Hung LIN, Chiayi City (TW)

(21) Appl. No.: 19/177,879

(22) Filed: Apr. 14, 2025

(30) Foreign Application Priority Data
Jun. 5, 2024 (TW) 113120811

(51) Int. Cl. H10B 12/00; G11C 5/06; H10P 50/00; H10P 70/00

(52) U.S. Cl. CPC H10B 12/01; H10P 50/69; H10P 50/71; H10P 70/27; G11C 5/063

(57) ABSTRACT

A method of manufacturing a memory device is provided. The method includes providing a substrate and forming a patterned photoresist over the substrate. The method includes using the patterned photoresist as a mask and performing a first etching process on the substrate to form a first opening in the substrate. The method further includes conformally forming a spacer material layer on the substrate and performing an etching-back process on the spacer material layer to form a spacer on sidewalls of the first opening. The method further includes using the spacer as a mask and performing a second etching process on the bottom of the first opening to form a second opening in the substrate. The first opening and the second opening collectively form a contact opening.

### CROSS REFERENCE TO RELATED APPLICATIONS

This Application claims priority of Taiwan Patent Application No. 113120811 filed on Jun. 5, 2024, the entirety of which is incorporated by reference herein.

### BACKGROUND

### Technical Field

The present disclosure relates to semiconductor technology, and in particular it relates to methods of manufacturing memory devices.

### Description of the Related Art

In the current process of forming memory devices (e.g., dynamic random-access memory (DRAM) with buried word lines), the component dimensions are continuously being scaled down, however this also reduces the process margin. For example, after forming buried word lines, the subsequent formation of bit line contacts may cause the distance between the buried word lines and the bit line contacts to be too close. This is due to process variations, and may result in leakage current, impacting the reliability of the device.

### BRIEF SUMMARY

The present disclosure provides a method of manufacturing a memory device. The method includes providing a substrate and forming a patterned photoresist over the substrate. The method includes using the patterned photoresist as a mask and performing a first etching process on the substrate to form a first opening in the substrate. The method further includes conformally forming a spacer material layer on the substrate and performing an etching-back process on the spacer material layer to form a spacer on sidewalls of the first opening. The method further includes using the spacer as a mask and performing a second etching process on the bottom of the first opening to form a second opening in the substrate. The first opening and the second opening collectively form a contact opening.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1 to 7 illustrate cross-sectional views of intermediate stages of manufacturing the memory device according to the embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

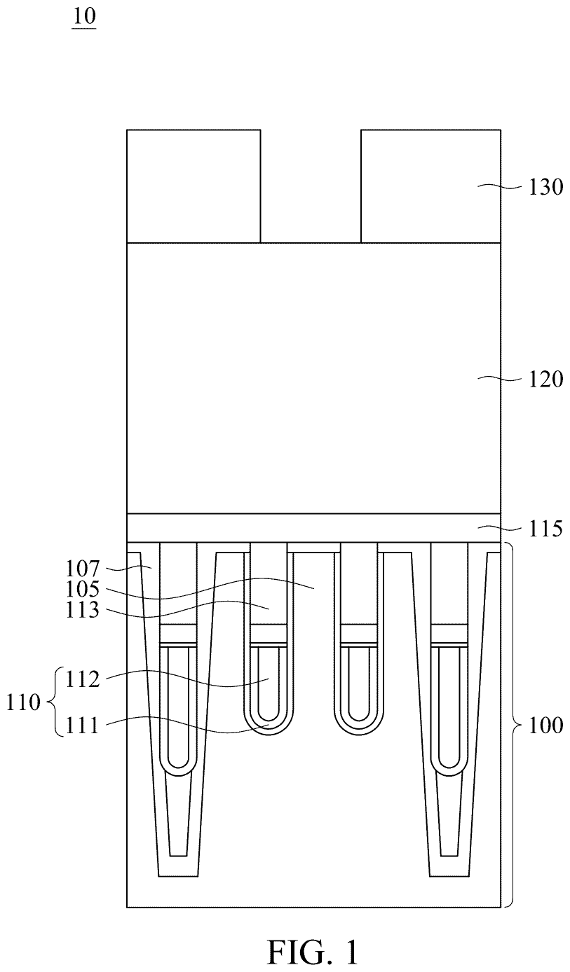

FIGS. 1 to 7 illustrate cross-sectional views of intermediate stages of manufacturing a memory device 10 according to the embodiments of the present disclosure. Referring to FIG. 1, a substrate 100 is provided. The substrate 100 may be an elemental semiconductor substrate, such as a silicon substrate or a germanium substrate; a compound semiconductor substrate, such as silicon carbide (SiC), gallium arsenide (GaAs), indium arsenide (InAs), or indium phosphide (InP) substrate; or an alloy semiconductor substrate, such as SiGe, SiGeC, GaAsP, or GaInP. In other embodiments, the substrate 100 may also be a semiconductor-on-insulator (SOI) substrate.

In FIG. 1, the substrate 100 has an active region 105 and an isolation structure 107. The substrate 100 includes a buried word line structure 110. The buried word line structure 110 may serve as the gate of the memory device 10, and may include a liner layer 111 and a gate electrode 112. In one embodiment, the buried word line structure 110 may be formed by patterning processes, deposition processes, and etching-back processes (not shown separately). The etching-back process may include anisotropic etching processes (or a directional etching processes), such as reactive ion etching, plasma etching, inductively coupled plasma etching, another dry etching process, or a combination thereof. In one embodiment, the liner layer 111 is formed of tungsten nitride (WN), titanium nitride (TiN), or tantalum nitride (TaN). In one embodiment, the gate electrode 112 is formed of a conductive material, such as doped polysilicon, metal, or metal nitride. In one embodiment, the liner layer 111 and the gate electrode 112 may be formed by a chemical vapor deposition (CVD) process, physical vapor deposition (PVD) process, atomic layer deposition (ALD) process, or a combination thereof.

The substrate 100 includes a protective layer 113 formed on the buried word line structure 110. In one embodiment, the formation of the protective layer 113 includes first depositing a nitride on the buried word line structure 110 using a deposition process, and then using an etching-back process to remove the nitride on the substrate 100, leaving the top surface of the remaining nitride level with the top surface of the substrate 100. In one embodiment, the deposition process may include chemical vapor deposition (CVD) process, physical vapor deposition (PVD) process, atomic layer deposition (ALD) process, or a combination thereof. In one embodiment, the etching-back process may include anisotropic etching processes (or directional etching processes), such as reactive ion etching, plasma etching, inductively coupled plasma etching, another dry etching process, or a combination thereof.

Still referring to FIG. 1. In one embodiment, a dielectric layer 115, a mask layer 120, and a patterned photoresist 130 are sequentially formed over the substrate 100. In one embodiment, the dielectric layer 115 may include a single layer or multiple layers, such as an oxide layer, a nitride layer, or a combination thereof. In one embodiment, the dielectric layer 115 may include a silicon oxide layer formed from tetraethylorthosilicate (TEOS), a silicon nitride layer, a silicon oxynitride layer, or a combination thereof. In one embodiment, the mask layer 120 may include a single layer or multiple layers, such as a spin-on coating carbon layer, a spin-on coating anti-reflective layer, or a combination thereof. In one embodiment, the dielectric layer 115 and the mask layer 120 may be formed by a spin-on coating process, deposition process, sputtering process, or a combination thereof. The deposition process may include a chemical vapor deposition (CVD) process, physical vapor deposition (PVD) process, atomic layer deposition (ALD) process, or a combination thereof.

In one embodiment, the formation of the patterned photoresist 130 may include one or more photolithography processes and one or more etching processes. A photoresist layer (not shown) may first be formed on the mask layer 120, and then the patterned photoresist 130 is formed through photolithography processes and etching processes.

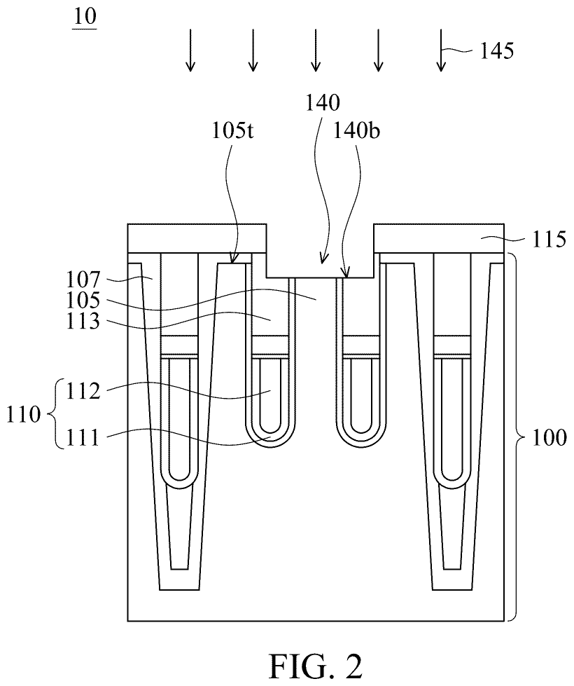

Referring to FIG. 2, the patterned photoresist 130 is used as a mask to perform a first etching process 145 on the substrate 100 to form a first opening 140 in the substrate 100. In one embodiment, the first opening 140 may penetrate through the dielectric layer 115 and extend into a portion of the substrate 100. More specifically, in one embodiment, after the first opening 140 is formed and before the first etching process 145, the bottom surface 140b of the first opening 140 is lower than the top surface 105t of the active region 105. After forming the first opening 140, the mask layer 120 may be removed during the first etching process 145, or the mask layer 120 may be removed using an ashing process. In one embodiment, the first etching process 145 may include an anisotropic etching process (or a directional etching process), such as reactive ion etching, plasma etching, inductively coupled plasma etching, another dry etching process, or a combination thereof.

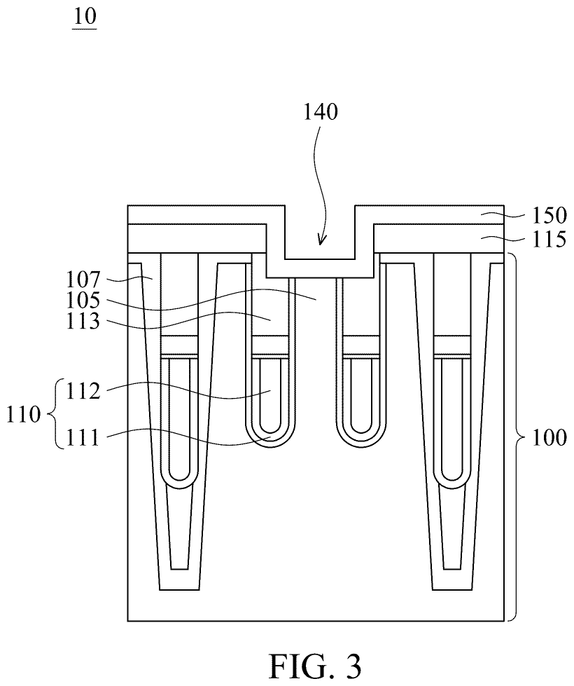

Referring to FIG. 3, a spacer material layer 150 is then formed over the substrate 100. More specifically, the spacer material layer 150 covers the sidewalls and the bottom of the first opening 140. In one embodiment, the spacer material layer 150 may include titanium nitride and may be formed by a chemical vapor deposition (CVD) process, atomic layer deposition (ALD) process, or a combination thereof.

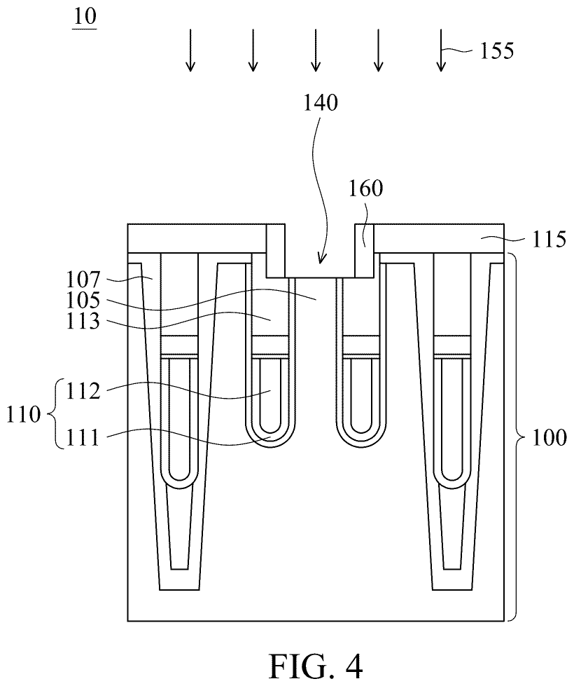

Referring to FIG. 4, an etching-back process 155 is then performed on the spacer material layer 150 to form a spacer 160 on the sidewall of the first opening 140. In one embodiment, while the etching-back process 155 is being performed, a portion of the spacer material layer 150 over the dielectric layer 115 and a portion of the spacer material layer 150 at the bottom of the first opening 140 are removed, leaving a portion of the spacer material layer 150 on the sidewalls of the first opening 140 to serve as the spacer 160. In one embodiment, the etching-back process 155 may include an anisotropic etching process (or a directional etching process), such as reactive ion etching, plasma etching, inductively coupled plasma etching, another dry etching process, or a combination thereof.

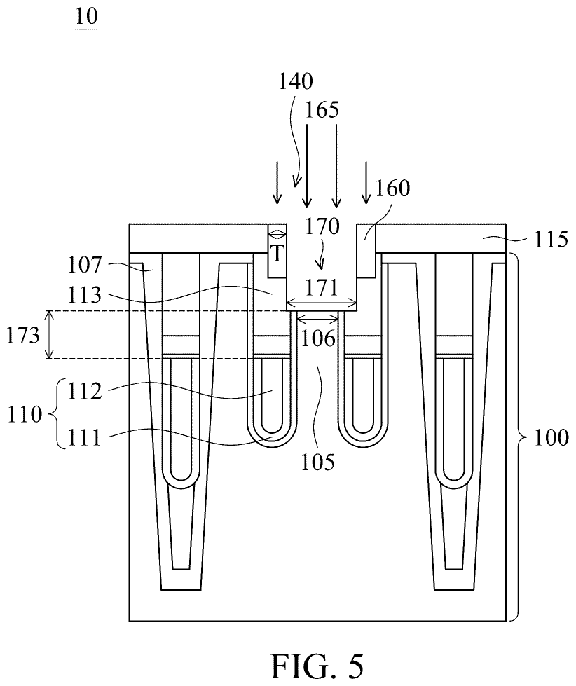

Referring to FIG. 5, the spacer 160 is used as a mask to perform a second etching process 165 at the bottom of the first opening 140 to form a second opening 170 in the substrate 100. In other words, the spacer 160 is used to reduce the width of the second opening 170, ensuring that a certain distance is maintained between the subsequently formed bit line contact and the buried word line structure 110. In one embodiment, the bottom width 171 of the second opening 170 is greater than the top width 106 of the active region 105. In one embodiment, the second etching process 165 may include an anisotropic etching process (or a directional etching process), such as reactive ion etching, plasma etching, inductively coupled plasma etching, or a combination of these dry etching methods.

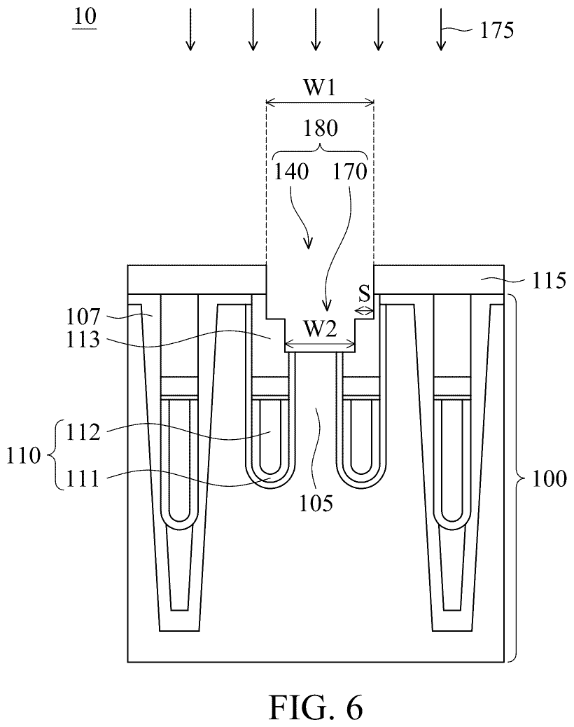

Referring to FIG. 6, after forming the second opening 170, a cleaning process 175 is performed to remove the spacer 160 and form a contact opening 180. After removing the spacer 160, the first opening 140 and the second opening 170 collectively form the contact opening 180. In the embodiment of the present disclosure, by dividing the process of forming the contact opening 180 into two steps and using the formation of the spacer 160, the contact opening 180 may have a structure with a wide top and a narrow bottom, effectively increasing the distance between the subsequently formed bit line contact and the buried word line structure 110, thus ensuring insulation between the bit line contact and the buried word line structure 110. In one embodiment, the thickness T of the spacer 160 on the sidewall of the first opening 140 corresponds to the distance S at which the sidewall of the second opening 170 is recessed relative to the sidewall of the first opening 140. In one embodiment, the contact opening 180 is formed on the active region 105 and exposes the upper surface of the active region 105. In one embodiment, the contact opening 180 is funnel-shaped. In one embodiment, the cleaning process 175 includes a low-temperature sulfuric acid hydrogen peroxide mixture cleaning process. In one embodiment, the width W1 of the first opening 140 is greater than the width W2 of the second opening 170. In one embodiment, the depth of the first opening 140 is greater than the depth of the second opening 170.

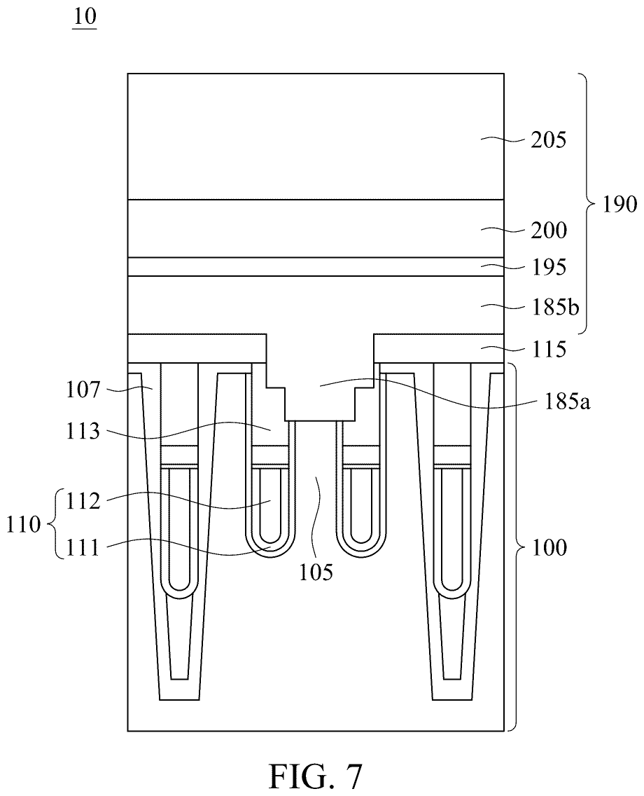

Referring to FIG. 7, after forming the second opening 170, a conductor layer 185a is formed to fill the contact opening 180, and a bit line structure 190 is formed over the conductor layer 185a. More specifically, the conductor layer 185a fills the contact opening 180 to serve as the bit line contact. In one embodiment, the bit line structure 190 may include a conductor layer 185b, a conductive layer 195, a dielectric layer 200, and a cap layer 205. It should be noted that the conductor layer 185a and conductor layer 185b may be sequentially formed in the same process, and there may not be a distinct interface between conductor layer 185a and the conductor layer 185b. After forming the conductor layer 185a (e.g., fully filling the contact opening 180), the conductor layer 185b may continue to be formed to further cover the top surfaces of the conductor layer 185a and the dielectric layer 115. After forming the conductor layer 185b, the conductive layer 195, the dielectric layer 200, and the cap layer 205 continue to be formed over the conductor layer 185b to form the bit line structure 190. In one embodiment, the conductor layer 185a is in direct contact with the sidewall of the contact opening 180. In one embodiment, the materials for the conductor layers 185a and the conductor layers 185b may include doped polysilicon, metal, or metal nitride, and may be formed by a chemical vapor deposition (CVD) process, physical vapor deposition (PVD) process, atomic layer deposition (ALD) process, or a combination thereof. In one embodiment, the conductive layer 195 may include doped polysilicon, metal, or metal nitride, such as tungsten (W), titanium (Ti), and titanium nitride. In one embodiment, the dielectric layer 200 and the cap layer 205 may include silicon oxide, silicon nitride, or a combination thereof.

After forming the bit line contact and the bit line structure 190, other semiconductor processes may be continued to form various features and components of the memory device 10, which will not be described herein.

In summary, the embodiment of the present disclosure forms the opening of the bit line contact in two steps, and with the formation of the spacers, enables the formed bit line contact to maintain a certain distance from the buried word line structure below, thereby ensuring insulation between the bit line contact and the buried word line structure, thereby effectively prevents the generation of leakage currents and maintains the electrical performance of the memory device. It should be understood that not all advantages have been necessarily discussed here, and not all embodiments require specific advantages, and other embodiments may offer different advantages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a memory device, comprising:
providing a substrate;
forming a patterned photoresist over the substrate;
using the patterned photoresist as a mask, and performing a first etching process on the substrate to form a first opening in the substrate;
conformally forming a spacer material layer on the substrate;
performing an etching-back process on the spacer material layer to form a spacer on sidewalls of the first opening; and
using the spacer as a mask and performing a second etching process on the bottom of the first opening to form a second opening in the substrate,
wherein the first opening and the second opening collectively form a contact opening.

2. The method as claimed in claim 1, wherein the substrate comprises an active region, and the contact opening is formed on the active region and exposes an upper surface of the active region.

3. The method as claimed in claim 2, wherein after forming the first opening, a bottom surface of the first opening is lower than a top surface of the active region before the first etching process.

4. The method as claimed in claim 2, wherein a bottom width of the second opening is greater than a top width of the active region.

5. The method as claimed in claim 1, wherein a width of the first opening is greater than a width of the second opening.

6. The method as claimed in claim 1, wherein the contact opening is funnel-shaped.

7. The method as claimed in claim 1, wherein after forming the second opening, the method further comprises:
forming a conductor layer to fill the contact opening; and
forming a bit line structure over the conductor layer.

8. The method as claimed in claim 7, wherein the conductor layer is in direct contact with a sidewall of the contact opening.

9. The method as claimed in claim 1, wherein a thickness of the spacer on a sidewall of the first opening corresponds to a distance from a sidewall of the second opening to a sidewall of the first opening.

10. The method as claimed in claim 1, wherein during the etching-back process, a portion of the spacer material layer at a bottom of the first opening is removed.

11. The method as claimed in claim 1, wherein after forming the second opening, the method further comprises:
performing a cleaning process to remove the spacer and form the contact opening.

12. The method as claimed in claim 11, wherein the cleaning process comprises a low-temperature sulfuric acid hydrogen peroxide mixture cleaning process.

13. The method as claimed in claim 1, wherein the first etching process comprises reactive ion etching, plasma etching, or inductively coupled plasma etching.

14. The method as claimed in claim 1, wherein the second etching process comprises reactive ion etching, plasma etching, or inductively coupled plasma etching.

15. The method as claimed in claim 1, wherein before forming the patterned photoresist, a dielectric layer and a mask layer are sequentially formed over the substrate.

16. The method as claimed in claim 15, wherein the first opening penetrates through the dielectric layer and extends into a portion of the substrate.

17. The method as claimed in claim 1, wherein a top width of the contact opening is greater than a bottom width of the contact opening.

18. The method as claimed in claim 1, wherein a depth of the first opening is greater than a depth of the second opening.

19. The method as claimed in claim 1, wherein the spacer material layer comprises titanium nitride, and the spacer material layer is formed by a chemical vapor deposition process, atomic layer deposition process, or a combination thereof.

20. The method as claimed in claim 1, wherein the substrate comprises a buried word line structure.
